(19) United States
(12) Patent Application Publication
(10) Pub. No.: US 2007/0164360 A1
(43) Pub. Date: Jul. 19, 2007

(54) Semiconductor device and method of fabricating the same

(75) Inventors: Tetsu Morooka, Tokyo (JP); Makoto Fujiwara, Tokyo (JP); Nobutoshi Aoki, Tokyo (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/645,806

(22) Filed: Dec. 27, 2006

(30) Foreign Application Priority Data
Dec. 28, 2005 (JP) 2005-379187

(51) Int. Cl. H01L 27/12

(52) U.S. Cl. 257/347

(57) ABSTRACT

A semiconductor device has a supporting substrate applied with a predetermined potential, an insulating layer formed on the supporting substrate, a semiconductor layer formed on the insulating layer, a FDSOI transistor formed on the semiconductor layer and including a source region, a drain region, and a channel region, the channel region being formed between the source region and the drain region, and a high-concentration impurity region formed in a vicinity of a surface of the supporting substrate at least just below the channel region, in which an average impurity concentration in the vicinity of the surface of the supporting substrate just below the channel region is not lower than an impurity concentration of the channel region.

### CROSS-REFERENCE TO RELATED APPLICATION

This application is based upon and claims the benefit of priority from prior Japanese Patent Application No. 2005-379187, filed on Dec. 28, 2005, the entire contents of which are incorporated herein by reference.

### BACKGROUND OF THE INVENTION

The present invention relates to a semiconductor device and, in more particularly, to a semiconductor device provided with a plurality of transistors having different threshold voltages.

In recent years, the power consumption of semiconductor devices has increased in accordance with the high integration and the speeding up with the miniaturization of the semiconductor devices. Then, fully depleted silicon on insulator (FDSOI)-metal insulator semiconductor field effect transistors (MISFETs) are expected as the next generation low power consumption devices. The FDSOI-MISFETs are provided with high-performance, low power consumption, and design compatibility with bulk MISFETs.

It has been required to individually control threshold voltages of a plurality of transistors on a common substrate during manufacture of the FDSOI-MISFETs. In view of such circumstances, Japanese Patent KOKAI NO. 2002-299634 (JP-A-2002-299634) discloses a technique of implanting silicon ions into a silicon dioxide film of a SOI structure through a silicon layer on the silicon dioxide to form a fixed oxide film charge layer. This technique suppresses a variation of the threshold voltage due to a variation of silicon film thickness. Further, Japanese Patent KOKAI NO. 2003-69023 (JP-A-2003-69023) discloses a technique of implanting first and second conductivity types of impurities, of which the first conductivity type impurities increases a threshold voltage and the second conductivity type impurities decreases the threshold voltage, into different depths of a SOI film. This technique inhibits a variation of the threshold voltages due to a variation of silicon film thicknesses.

However, the purpose of these known techniques is not to shift threshold voltages aggressively but to suppress the variation of threshold voltages of a plurality of transistors.

### BRIEF SUMMARY OF THE INVENTION

A semiconductor device, according to one embodiment of the present invention, comprises:

a supporting substrate applied with a predetermined potential;

an insulating layer formed on the supporting substrate;

a semiconductor layer formed on the insulating layer;

a FDSOI transistor formed on the semiconductor layer and including a source region, a drain region, and a channel region, the channel region being formed between the source region and the drain region; and

a high-concentration impurity region formed in a vicinity of a surface of the supporting substrate at least just below the channel region,

wherein an average impurity concentration in the vicinity of the surface of the supporting substrate just below the channel region is not lower than an impurity concentration of the channel region.

A semiconductor device, according to another embodiment of the present invention, comprises:

a supporting substrate applied with a predetermined potential;

an insulating layer formed on the supporting substrate;

a semiconductor layer formed on the insulating layer;

a first FDSOI transistor formed on the semiconductor layer and including a first source region, a first drain region, and a first channel region, the first channel region being formed between the first source region and the first drain region;

a first high-concentration impurity region formed in a vicinity of a surface of the supporting substrate at least just below the first channel region;

a second FDSOI transistor formed on the semiconductor layer and including a second source region, a second drain region, and a second channel region, the second channel region being formed between the second source region and the second drain region; and

a second high-concentration impurity region formed in the vicinity of the surface of the supporting substrate at least just below the second channel region,

wherein an average impurity concentration in the vicinity of the surface of the supporting substrate just below the first channel region is not lower than an impurity concentration of the first channel region, and

an average impurity concentration in the vicinity of the surface of the supporting substrate just below the second channel region is not lower than an impurity concentration of the second channel region and is different from the average impurity concentration in the vicinity of the surface of the supporting substrate just below the first channel region.

A method of fabricating a semiconductor device, according to still another embodiment of the present invention, comprises:

implanting impurities into a semiconductor substrate including a supporting substrate, an insulating layer formed on the supporting substrate, and a semiconductor layer formed on the insulating layer, the impurities being implanted through the semiconductor layer to form a high-concentration impurity region in a vicinity of a surface of the supporting substrate; and

forming a FDSOI transistor having a channel region which has an impurity concentration not higher than an average impurity concentration in the vicinity of the surface of the supporting substrate just below the channel region.

### BRIEF DESCRIPTION OF THE DRAWING

The embodiments according to the invention will be explained below referring to the drawings, wherein:

FIG. 1 is a schematic cross sectional view of a semiconductor device in a first embodiment according to the present invention;

FIGS. 2A to 2D are schematic cross sectional views showing steps for fabricating a semiconductor device in the first embodiment according to the present invention;

FIG. 3 is a graph showing a relationship between the Vt (threshold voltage) shift and a BOX layer thickness of a semiconductor device in the first embodiment according to the present invention;

FIG. 4 is a schematic cross sectional view of a semiconductor device in a second embodiment according to the present invention; and

FIGS. 5A to 5D are schematic cross sectional views showing steps for fabricating a semiconductor device in the second embodiment according to the present invention.

### DETAILED DESCRIPTION OF THE INVENTION

Next, a semiconductor device in the embodiments according to the invention will be explained in more detail in conjunction with the appended drawings.

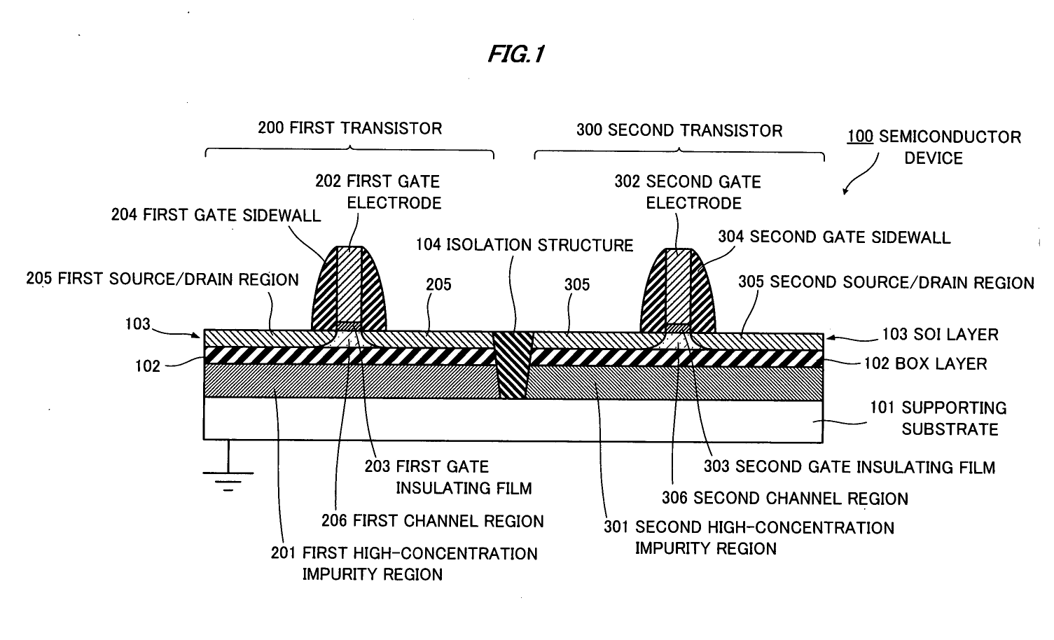

FIG. 1 is a schematic cross sectional view of a semiconductor device in the first embodiment according to the present invention. A semiconductor device 100 comprises a first transistor 200 and a second transistor 300. The first transistor 200 and the second transistor 300 are FDSOI, and separated by an isolation structure 104 which, for example, has shallow trench isolation (STI) structure.

The first transistor 200 has a grounded supporting substrate 101 composed of Si or the like, a buried oxide (BOX) layer 102 composed of SiO₂ or the like as an insulating layer formed on the supporting substrate 101, a SOI layer 103 composed of Si single crystal or the like as a semiconductor layer formed on the BOX layer 102, and a first source/drain region 205 and a first channel region 206 formed in the SOI layer 103.

In addition, the first transistor 200 has a first gate electrode 202 formed through a first insulating film 203 on the SOI layer 103, and a first gate sidewall 204 formed on both side of the first gate electrode 202. Note that a gate length of the first transistor 200 is 30 nm, for example.

The second transistor 300 has a second source/drain region 305 and a second channel region 306 in the SOI layer 103.

In addition, the second transistor 300 has a second gate electrode 302 formed through a second insulating film 303 on the SOI layer 103, and a second gate sidewall 304 formed on both side of the second gate electrode 302. Note that a gate length of the second transistor 300 is 30 nm, for example.

In addition, a first high-concentration impurity region 201 and a second high-concentration impurity region 301 are formed in the vicinity of a surface (i.e. a depth of 50 nm to 100 nm below the upper surface) of the supporting substrate 101 just below the first channel region 206 and just below the second channel region 306, respectively. Here, impurity concentration of the first high-concentration impurity region 201 is not lower than that of the first channel region 206, and impurity concentration of the second high-concentration impurity region 301 is not lower than that of the second channel region 306. The impurity concentrations of the first and second high-concentration impurity regions 201 and 301 are preferably not lower than 1×10¹⁸ cm⁻³ and not higher than 1×10²¹ cm⁻³. This is because the effect of forming the first and second high-concentration impurity regions 201 and 301 is insufficient when the impurity concentrations are lower than 1×10¹⁸ cm⁻³, and the effect is saturated when the impurity concentrations are higher than 1×10²¹ cm⁻³.

In addition, the impurity concentration of the first high-concentration impurity region 201 and that of the second high-concentration impurity region 301 are different from each other. For example, when the impurity concentration of the second high-concentration impurity region 301 is higher than that of the first high-concentration impurity region 201, a threshold voltage of the second transistor 300 is higher than that of the first transistor 200.

The SOI layer 103 and the BOX layer 102 have such thicknesses that impurities are implanted through the SOI layer 103 and the BOX layer 102 into the vicinity of the surface of the supporting substrate 101 from above. For example, the thickness of the SOI layer 103 is not higher than 15 nm and is preferably 5 to 15 nm, and the thickness of the BOX layer 102 is not higher than 30 nm and is preferably 5 to 30 nm.

In the first embodiment of the invention, a combination of conductivity types of the first and second transistors 200 and 300 may be selected from the below table.

| | FIRST TRANSISTOR | SECOND TRANSISTOR |
|---|---|---|
| COMBINATION | 200 | 300 |
| 1 | p-type | p-type |
| 2 | n-type | p-type |
| 3 | p-type | n-type |
| 4 | n-type | n-type |

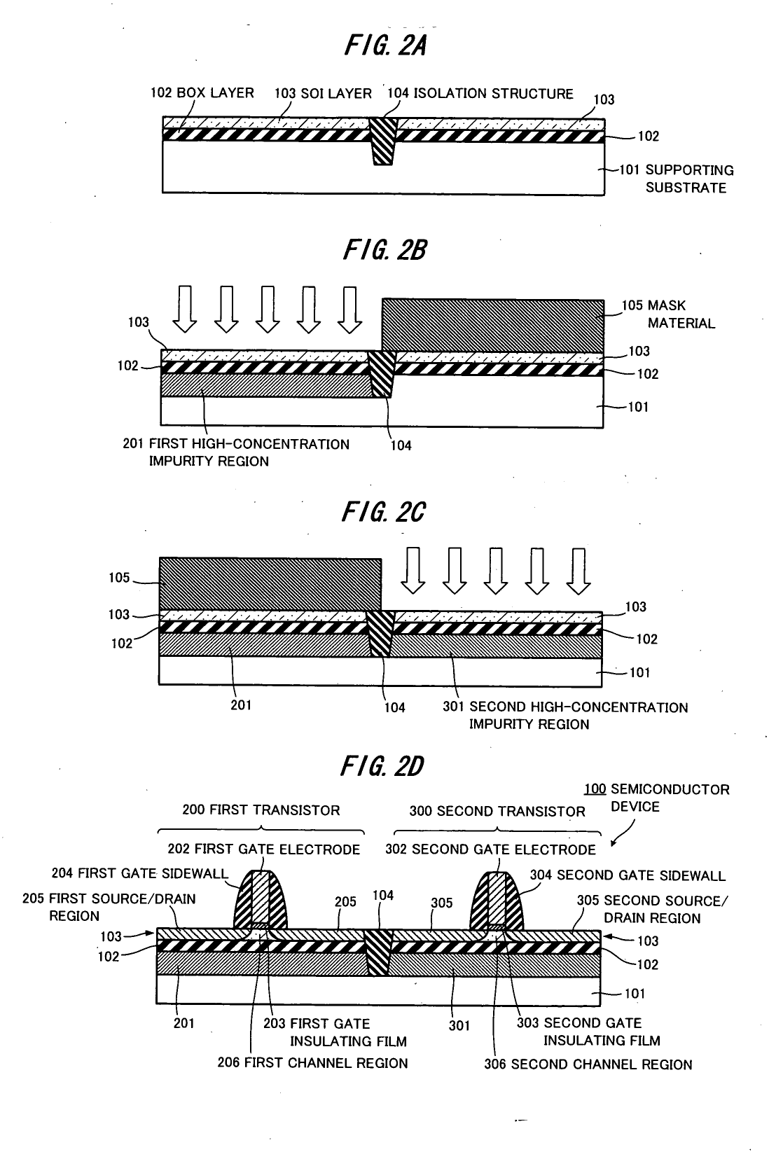

FIGS. 2A to 2D are schematic cross sectional views showing the steps for fabricating a semiconductor device in the first embodiment according to the present invention.

Firstly, as shown in FIG. 2A, the isolation structure 104 is formed on a SOI substrate including the supporting substrate 101, the BOX layer 102, and the SOI layer 103.

Next, as shown in FIG. 2B, a surface of the SOI layer 103 in a region for the second transistor 300 is masked by a mask material 105, and impurities are implanted through the SOI layer 103 into the SOI substrate. The impurities are p-type impurity ions such as B and BF₂ in the case of an n-type MISFET, and n-type impurity ions such as As and P in the case of an p-type MISFET. The implanted impurities reach the vicinity of the surface of the supporting substrate 101 through the SOI layer 103 and the BOX layer 102, and form the first high-concentration impurity region 201.

Next, as shown in FIG. 2C, a surface of the SOI layer 103 in a region for the first transistor 200 is masked by a mask material 105, and impurities are implanted through the SOI layer 103 into the SOI substrate. The impurities are p-type impurity ions such as B and BF₂ in the case of the n-type MISFET, and n-type impurity ions such as As and P in the case of the p-type MISFET. The implanted impurities reach the vicinity of the surface of the supporting substrate 101 through the SOI layer 103 and the BOX layer 102, and form the second high-concentration impurity region 301.

In forming the first and second high-concentration impurity region 201 and 301, an implanted amount of impurities is adjusted to differ between impurity concentrations of the first high-concentration impurity region 201 and that of the second high-concentration impurity region 301.

Next, as shown in FIG. 2D, the first and second insulating films 203 and 303 and the first and second gate electrodes 202 and 302 are formed through a photo resist process, a reactive ion etching (RIE) process, or the like. Then, impurities are implanted into the SOI layer 103 from the top surface thereof so that the first and second source/drain regions 205 and 305 are formed. The impurities are n-type impurity ions such as As and P in the case of the n-type MISFET, and p-type impurity ions such as B and BF₂ in the case of the p-type MISFET. On both sides of the first and second gate electrodes 202 and 302, the first and second gate sidewalls 204 and 304 are formed, respectively, through an insulating film deposition process, the RIE process, or the like.

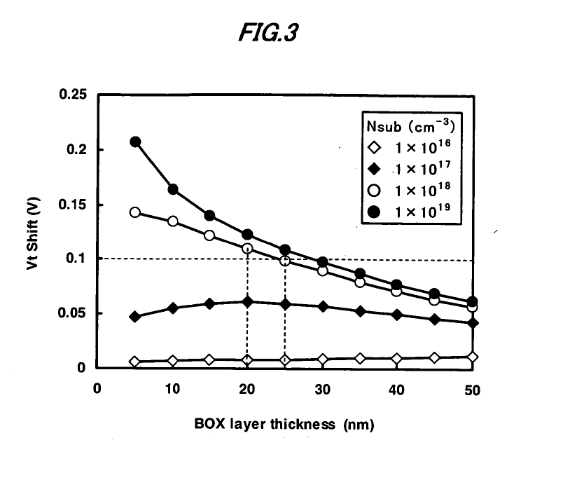

FIG. 3 is a graph showing a relationship between the Vt (threshold voltage) shift (V) and the BOX layer thickness (nm) of a semiconductor device in the first embodiment according to the present invention. The Vt shift (V) indicated along the vertical axis is a shift amount of threshold voltages of semiconductor devices having the first or second high-concentration impurity region 201 or 301 doped with impurities having impurity concentrations of 1×10¹⁶ cm⁻³, 1×10¹⁷ cm⁻³, 1×10¹⁸ cm⁻³, and 1×10¹⁹ cm⁻³ as indicated by “Nsub” in FIG. 3, wherein the shift amount is a value shifted form a reference value of a threshold voltage which is obtained in the semiconductor device 100 having the first or second high-concentration impurity region 201 or 301 doped with impurities having an impurity concentration of 1×10¹⁵ cm⁻³, and the reference value coincides with the horizontal axis in FIG. 3.

In FIG. 3, symbols “⋄” show values when the impurity concentration is 1×10¹⁶ cm⁻³, symbols “♦” show values when the impurity concentration is 1×10¹⁷ cm⁻³, symbols “◯” show values when the impurity concentration is 1×10¹⁸ cm⁻³, and symbols “●” show values when the impurity concentration is 1×10¹⁹ cm ⁻³.

Note that the gate length is 30 nm, the thickness of SOI layer is 10 nm, and implanted impurities are boron ions.

It is understood from FIG. 3 that, where a threshold voltage is shifted by 0.1 V or more as compared to a threshold voltage of the semiconductor device 100 having the first or second high-concentration impurity region 201 or 301 having an impurity concentration of 1×10¹⁵ cm⁻³, a film thickness of the BOX layer 102 should be 20 nm or less in a semiconductor device having the first or second high-concentration impurity region 201 or 301 having an impurity concentration of 1×10¹⁸ cm⁻³, while a film thickness of the BOX layer 102 should be 25 nm or less in a semiconductor device having the first or second high-concentration impurity region 201 or 301 having an impurity concentration of 1×10¹⁹ cm⁻³.

According to the first embodiment of the present invention, the impurities are implanted to the vicinity of the surface of the supporting substrate 101 through the SOI layer 103 and the BOX layer 102 to form the first and second high-concentration impurity regions 201 and 301. Here, the impurity concentration of the first and second high-concentration impurity regions 201 and 301 are higher than or equal to that of the first and second channel regions 206 and 306, respectively. As a result, it is possible to control the threshold voltages of the first and second transistors 200 and 300 individually.

In addition, by changing the impurity concentration of the high-concentration impurity region of each transistor, it is possible to form a plurality of the transistors having different threshold voltages on a substrate.

In addition, it is possible to inhibit the decrease of carrier mobility of the transistors because the threshold voltages of the transistors are controlled without the increase of the impurity concentrations of the first and second channel regions 206 and 306.

In addition, the variation of threshold voltages is significant if threshold voltages are controlled by the impurity concentrations in channel regions, because threshold voltages control needs high impurity concentrations. However, according to the first embodiment of the present invention, it is possible to inhibit the variation of threshold voltages because the threshold voltages of the transistors are controlled without the increase of the impurity concentrations of the first and second channel regions 206 and 306.

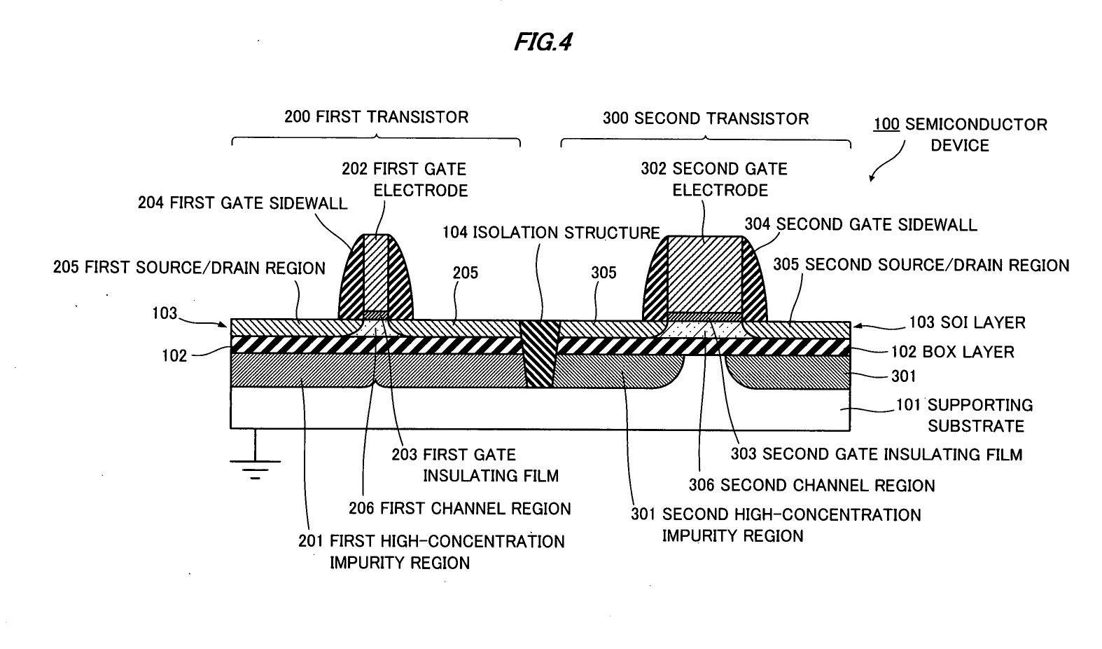

FIG. 4 is a schematic cross sectional view of a semiconductor device in the second embodiment according to the present invention. A semiconductor device 100 includes a first transistor 200 and a second transistor 300. The first transistor 200 and the second transistor 300 are FDSOI, and separated by an isolation structure 104. Note that same parts as the first embodiment such as materials of each member are omitted here for the sake of simplicity.

The first transistor 200 has a grounded supporting substrate 101, a BOX layer 102 as an insulating layer formed on the supporting substrate 101, a SOI layer 103 as a semiconductor layer formed on the BOX layer 102, and a first source/drain region 205 and a first channel region 206 formed in the SOI layer 103.

In addition, the first transistor 200 has a first gate electrode 202 formed on the SOI layer 103 through a first insulating film 203, and a first gate sidewall 204 formed on both side of the first gate electrode 202. Note that a gate length of the first transistor 200 is 20 nm, for example.

The second transistor 300 has a second source/drain region 305 and a second channel region 306 in the SOI layer 103.

In addition, the second transistor 300 has a second gate electrode 302 formed on the SOI layer 103 through a second insulating film 303, and a second gate sidewall 304 formed on both sides of the second gate electrode 302. Note that a gate length of the second transistor 300 is longer than that of the first transistor 200 and, for example, it is 200 nm.

The SOI layer 103 and the BOX layer 102 have such thicknesses that impurities are implanted through the SOI layer 103 and the BOX layer 102 into the vicinity of the surface of the supporting substrate 101. For example, the thickness of the SOI layer 103 is not higher than 15 nm and is preferably 5 to 15 nm, and the thickness of the BOX layer 102 is not higher than 30 nm and is preferably 5 to 30 nm.

In addition, a first high-concentration impurity region 201 and a second high-concentration impurity region 301 are formed in the vicinity of the surface (i.e. a depth of 50 nm to 100 nm below the upper surface) of the supporting substrate 101 just below the BOX layer 102 in the regions for the first transistor 200 and the second transistor 300, respectively. Here, an average impurity concentration of the vicinity of the surface of the supporting substrate 101 just below the first channel region 206 is not lower than impurity concentration of the first channel region 206, and an average impurity concentration of the vicinity of the surface of the supporting substrate 101 just below the second channel region 306 is not lower than impurity concentration of the second channel region 306. The average impurity concentrations of the vicinities of the surface of the supporting substrate 101 just below the first and second channel regions 206 and 306 are not lower than 1×10¹⁸ cm⁻³ and are not higher than 1×10²¹ cm⁻³. This is because the effect of forming the first and second high-concentration impurity regions 201 and 301 is insufficient when the impurity concentrations are lower than 1×10¹⁸ cm⁻³, and the effect is saturated when the impurity concentrations are higher than 1×10²¹ cm⁻³.

In addition, as shown in FIG. 4, the average impurity concentration of the vicinity of the surface of the supporting substrate 101 just below the first channel region 206 is higher than that just below the second channel region 306, because a ratio of the region occupied by the first high-concentration impurity region 201 in the vicinity of the surface of the supporting substrate 101 just below the first channel region 206 is higher than a ratio of the region occupied by the second high-concentration impurity region 301 in the vicinity of the surface of the supporting substrate 101 just below the second channel region 306.

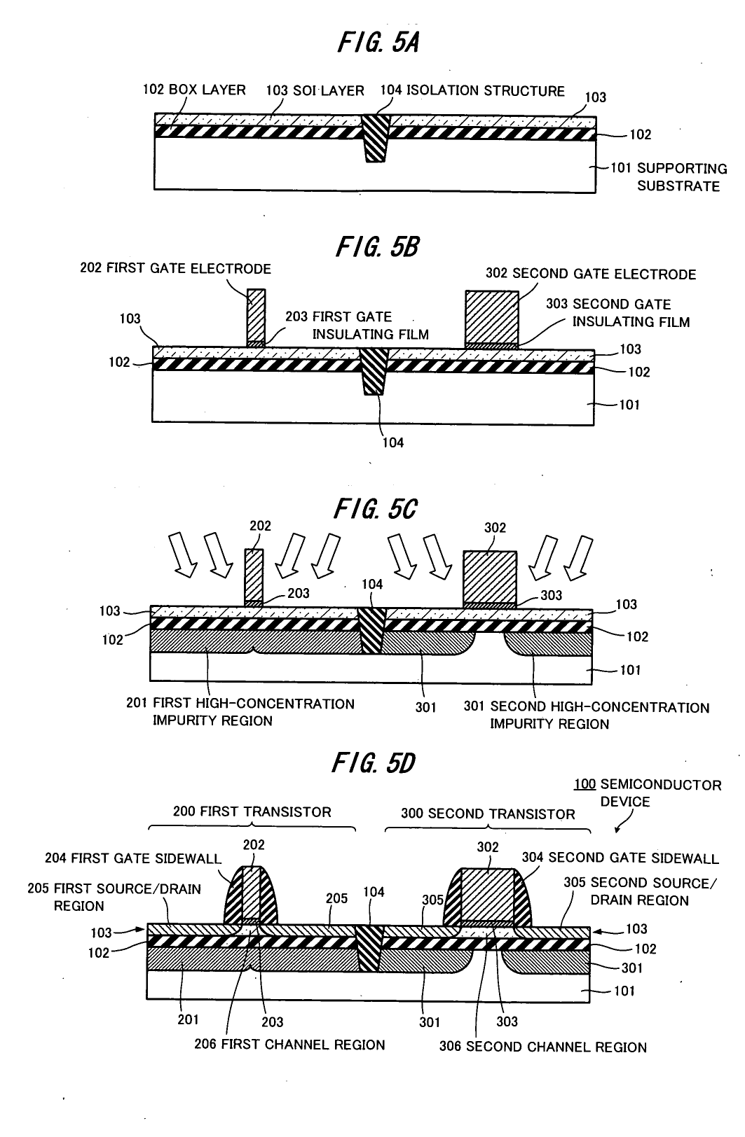

FIGS. 5A to 5D are schematic cross sectional views showing the process for fabricating a semiconductor device in the second embodiment according to the present invention.

Firstly, as shown in FIG. 5A, the isolation structure 104 is formed on a SOI substrate including the supporting substrate 101, the BOX layer 102, and the SOI layer 103.

Next, as shown in FIG. 5B, the first and second insulating films 203, 303 and the first and second gate electrodes 202, 302 are formed on the SOI layer 103 through a photo resist process, a reactive ion etching (RIE) process, or the like.

Next, as shown in FIG. 5C, impurities are implanted through the SOI layer 103 into the SOI substrate. The impurities are p-type impurity ions such as B and BF₂ in the case of the n-type MISFET, and n-type impurity ions such as As and P in the case of the p-type MISFET. The implanted impurities reach the vicinity of the surface of the supporting substrate 101 through the SOI layer 103 and the BOX layer 102, and form the first and second high-concentration impurity region 201 and 301.

In this bout, although the first and second gate electrodes 202 and 302 work as mask materials, the first and second high-concentration impurity regions 201 and 301 are formed in the region just below the first and second channel regions 206 and 306, respectively, because impurities are implanted at a predetermined angle such as 20° with the vertical direction.

Since widths of the first gate electrode 202 and the first insulating film 203 are narrow, the impurities implanted at the predetermined angle with the vertical direction reach the vicinity of a point, which is just below a center in the longitudinal direction of a channel length of the first channel region 206, from both side of the first gate electrode 202 and the first insulating film 203 in the vicinity of the surface of the supporting substrate 101. As a result, the ratio of the region occupied by the first high-concentration impurity region 201 just below the first channel region 206 is relatively high.

On the other hand, since the widths of the second gate electrode 302 and a second insulating film 303 are broader than the widths of the first gate electrode 202 and the first insulating film 203, the impurities implanted at the predetermined angle with the vertical direction do not reach the vicinity of a point, which is just below a center in the longitudinal direction of a channel length of the second channel region 306, from both side of the second gate electrode 302 and a second insulating film 303 in the vicinity of the surface of the supporting substrate 101. As a result, the ratio of the region occupied by the second high-concentration impurity region 301 just below the second channel region 306 is lower than the ratio of the region occupied by the first high-concentration impurity region 201 just below the first channel region 206. Thus, the average impurity concentration of the vicinity of the surface of the supporting substrate 101 just below the first channel region 206 is higher than that just below the second channel region 306.

Next, as shown in FIG. 5D, impurities are implanted into the SOI layer 103 from the top surface thereof so that the first and second source/drain regions 205 and 305 are formed. The impurities are n-type impurity ions such as As and P in the case of an n-type MISFET, and p-type impurity ions such as B and BF₂ in the case of an p-type MISFET. On both side of the first and second gate electrodes 202 and 302, the first and second gate sidewalls 204 and 304 are formed, respectively, through an insulating film deposition process, the RIE process, or the like.

According to the second embodiment of the present invention, by changing the gate length of the gate electrode which works as the mask material, it is possible to control the ratio of the region occupied by the high-concentration impurity region just below the channel region in the vicinity of the surface of the supporting substrate, i.e. the average impurity concentration of the vicinity of the surface of the supporting substrate just below the channel region. Therefore, the effect the same as the first embodiment of the present invention is obtained. Especially, the second embodiment is effective at inhibiting the short channel effect in the first transistor 200 with the short gate length which is easy to have the significant short channel effect.

It should be noted that each of the above-mentioned first and second embodiments is merely an embodiment, the present invention is not intended to be limited thereto, and the various changes can be implemented without departing from the gist of the invention. For example, although two transistors having different threshold voltages are described in each of the first and second embodiments, the number of transistors having different threshold voltages is not limited to a specific number.

In addition, other insulating layers such as SiON may be used instead of the BOX layer. And, other semiconductor layers such as Ge single crystal may be used instead of the SOI layer.

In addition, the supporting substrate is connected to the ground in the first and second embodiments. However, it is not always necessary that the supporting substrate is connected to the ground, and the effect the same as the first and second embodiments can be obtained, as long as a predetermined potential is provided to the supporting substrate.

In addition, as in the case of the first embodiment, the impurity implantations into the high-concentration impurity regions in the regions for the first transistor and the second transistor may be implemented separately in the second embodiment.

In addition, the constituent elements of each of the above-mentioned first and second embodiments can be arbitrarily combined with each other without departing from the gist of the present invention.

What is claimed is:

1. A semiconductor device, comprising:
a supporting substrate applied with a predetermined potential;
an insulating layer formed on the supporting substrate;
a semiconductor layer formed on the insulating layer;
a FDSOI transistor formed on the semiconductor layer and including a source region, a drain region, and a channel region, the channel region being formed between the source region and the drain region; and
a high-concentration impurity region formed in a vicinity of a surface of the supporting substrate at least just below the channel region,
wherein an average impurity concentration in the vicinity of the surface of the supporting substrate just below the channel region is not lower than an impurity concentration of the channel region.

2. A semiconductor device according to claim 1, wherein the insulating layer is an oxide film having a thickness which is not higher than 30 nm.

3. A semiconductor device according to claim 1, wherein the semiconductor layer is a Si single crystal film having thickness which is not higher than 15 nm.

4. A semiconductor device according to claim 1, wherein the average impurity concentration in the vicinity of the surface of the supporting substrate just below the channel region is in a range of 1×10¹⁸ cm⁻³ to 1×10²¹ cm⁻³.

5. A semiconductor device according to claim 1, wherein an impurity concentration in the vicinity of the surface of the supporting substrate just below a center in a longitudinal direction of a channel length of the channel region is different from that just below an edge in the longitudinal direction of the channel length of the channel region.

6. A semiconductor device, comprising:
a supporting substrate applied with a predetermined potential;
an insulating layer formed on the supporting substrate;
a semiconductor layer formed on the insulating layer;
a first FDSOI transistor formed on the semiconductor layer and including a first source region, a first drain region, and a first channel region, the first channel region being formed between the first source region and the first drain region;
a first high-concentration impurity region formed in a vicinity of a surface of the supporting substrate at least just below the first channel region;
a second FDSOI transistor formed on the semiconductor layer and including a second source region, a second drain region, and a second channel region, the second channel region being formed between the second source region and the second drain region; and
a second high-concentration impurity region formed in the vicinity of the surface of the supporting substrate at least just below the second channel region,
wherein an average impurity concentration in the vicinity of the surface of the supporting substrate just below the first channel region is not lower than an impurity concentration of the first channel region, and
an average impurity concentration in the vicinity of the surface of the supporting substrate just below the second channel region is not lower than an impurity concentration of the second channel region and is different from the average impurity concentration in the vicinity of the surface of the supporting substrate just below the first channel region.

7. A semiconductor device according to claim 6, wherein the insulating layer is an oxide film having a thickness which is not higher than 30 nm.

8. A semiconductor device according to claim 6, wherein the semiconductor layer is a Si single crystal film having a thickness which is not higher than 15 nm.

9. A semiconductor device according to claim 6, wherein both of the average impurity concentrations in the vicinity of the surface of the supporting substrate just below the first and second channel regions are in a range of 1×10¹⁸ cm⁻³ to 1×10²¹ cm⁻³.

10. A semiconductor device according to claim 6, wherein:
the first FDSOI transistor has a first gate electrode, and
the second FDSOI transistor has a second gate electrode having a gate length different from that of the first gate electrode.

11. A semiconductor device according to claim 10, wherein:
the second gate electrode has the gate length longer than that of the first electrode, and
an impurity concentration in the vicinity of the surface of the supporting substrate just below a center in a longitudinal direction of a channel length of the second channel region is different from that just below an edge in the longitudinal direction of the channel length of the second channel region.

12. A method of fabricating a semiconductor device, comprising:
implanting impurities into a semiconductor substrate including a supporting substrate, an insulating layer formed on the supporting substrate, and a semiconductor layer formed on the insulating layer, the impurities being implanted through the semiconductor layer to form a high-concentration impurity region in a vicinity of a surface of the supporting substrate; and
forming a FDSOI transistor having a channel region which has an impurity concentration not higher than an average impurity concentration in the vicinity of the surface of the supporting substrate just below the channel region.

13. A method of fabricating a semiconductor device according to claim 12, wherein the insulating layer is an oxide film having a thickness which is not higher than 30 nm.

14. A method of fabricating a semiconductor device according to claim 12, wherein the semiconductor layer is a Si single crystal film having a thickness which is not higher than 15 nm.

15. A method of fabricating a semiconductor device according to claim 12, wherein the high-concentration impurity region is formed so that the average impurity concentration in the vicinity of the surface of the supporting substrate just below the channel region is in a range of 1×10¹⁸ cm⁻³ to 1×10²¹ cm⁻³.

16. A method of fabricating a semiconductor device according to claim 12, wherein:
forming the FDSOI transistor comprises forming a gate electrode, and
forming the high-concentration impurity region is performed before forming the gate electrode.

17. A method of fabricating a semiconductor device according to claim 16, wherein:
forming the high-concentration impurity region comprises forming a first high-concentration impurity region and forming a second high-concentration impurity region having an impurity concentration different from that of the first high-concentration impurity region, and
forming the FDSOI transistor comprises forming a first FDSOI transistor just above the first high-concentration impurity region and forming a second FDSOI transistor just above the second high-concentration impurity region.

18. A method of fabricating a semiconductor device according to claim 12, wherein forming the high-concentration impurity region comprises implanting the impurities using a gate electrode of the FDSOI transistor as a mask material to form the high-concentration impurity region, such that an impurity concentration in the vicinity of the surface of the supporting substrate just below a center in a longitudinal direction of a channel length of the channel region is different from that just below an edge in the longitudinal direction of the channel length of the channel region.

19. A method of fabricating a semiconductor device according to claim 18, wherein the impurities are implanted from above the semiconductor layer at a predetermined angle with a vertical direction using the gate electrode as the mask material.

20. A method of fabricating a semiconductor device according to claim 12, wherein:
forming the FDSOI transistor comprises forming a first FDSOI transistor having a first gate electrode and a first channel region and forming a second FDSOI transistor having a second gate electrode which has a gate length longer than that of the first gate electrode and a second channel region, and
forming the high-concentration impurity region comprises implanting the impurities from above the semiconductor layer at a predetermined angle with a vertical direction using the first and second gate electrodes as mask materials to form the high-concentration impurity region, so that an impurity concentration in the vicinity of the surface of the supporting substrate just below a center in a longitudinal direction of a channel length of the second channel region is different from that just below an edge in the longitudinal direction of the channel length of the second channel region.
